(19) United States
(12) Patent Application Publication
(10) Pub. No.: US 2013/0249063 A1
(43) Pub. Date: Sep. 26, 2013

(54) SHIELD PLATE, METHOD FOR MANUFACTURING A SEMICONDUCTOR DEVICE, AND SEMICONDUCTOR DEVICE

(71) Applicant: KABUSHIKI KAISHA TOSHIBA, Tokyo (JP)

(72) Inventors: Hironobu SHIBATA, Hyogo-ken (JP); Etsuo HAMADA, Hyogo-ken (JP)

(21) Appl. No.: 13/786,152

(22) Filed: Mar. 5, 2013

(30) Foreign Application Priority Data
Mar. 23, 2012 (JP) 2012-067608

(51) Int. Cl. H01L 23/552; H01L 21/326

(52) U.S. Cl. CPC H01L 23/552; H01L 21/326
USPC 257/659; 438/466

(57) ABSTRACT

An aspect of the present embodiment, there is provided a shield plate configured to cover a semiconductor substrate including a semiconductor device in which a first semiconductor element and a second semiconductor element are included, in implanting charged particles into the semiconductor substrate to provide a lifetime control layer in the semiconductor substrate, including, an alignment mark configured to align with respect to a semiconductor substrate, a first region configured to cover the first semiconductor element, and a second region configured to cover the second semiconductor element, a thickness of the second region being thinner than a thickness of the first region.

### CROSS REFERENCE TO RELATED APPLICATION

This application is based upon and claims the benefit of priority from prior Japanese Patent Application No. 2012-067608, filed on Mar. 23, 2012, the entire contents of which are incorporated herein by reference.

### FIELD

Exemplary embodiments described herein generally relate to a shield plate, to a method for manufacturing a semiconductor device, and to a semiconductor device.

### BACKGROUND

An insulated gate bipolar transistor (hereinafter, referred to as IGBT element) having both a low-resistance property of a bipolar transistor when the bipolar transistor is turned on and a fast-switching property of a metal-oxide semiconductor field-effect transistor (MOSFET) is used in various fields.

The IGBT element is often used in combination with a reverse-conducting diode (hereinafter, referred to as diode element) when used in an inverter circuit or the like. Such a semiconductor device using the combination of the IGBT element and the diode element is generally called a reverse-conducting insulated gate bipolar transistor.

A lifetime control layer is sometimes formed in the reverse-conducting insulated gate bipolar transistor in order to improve properties, for example, recovery property, when the diode element switches from forward bias to reverse bias.

The lifetime control layer is formed by radiating charged particles, for example, hydrogen ions or helium ions to a semiconductor substrate or by diffusing platinum (Pt) in a semiconductor substrate. A method for forming the lifetime control layer, the following method has been proposed, for example. Specifically, in the method, a metal layer is formed on a semiconductor substrate. The metal layer is selectively etched to form recesses at desired positions. Charged particles are implanted into the semiconductor substrate with the metal layer having the recesses as a mask. In such a manner, the lifetime control layer is formed.

However, in the conventional reverse-conducting insulated gate bipolar transistor, the charged particles are radiated or platinum is diffused over the entire semiconductor substrate. Therefore, the lifetime control layer is formed not only in the diode element but also in the IGBT element, which increases an on-resistance of the IGBT element. On the other hand, when the lifetime control layer is not formed in the diode element, the performance of the IGBT element is not deteriorated but the performance of the diode element cannot be improved.

### BRIEF DESCRIPTION OF THE DRAWINGS

FIG. 1 is a plan view showing a shield plate according to a first embodiment;

FIG. 2 is an enlarged view showing an alignment mark according to the first embodiment;

FIGS. 3A and 3B are enlarged views showing a region A according to the first embodiment;

FIG. 4 is a partially cross-sectional view showing the shield plate and a wafer according to the first embodiment;

FIGS. 5A to 5D are cross-sectional views showing a method for manufacturing a semiconductor device using the shield plate according to the first embodiment;

FIG. 6 is a cross-sectional view showing a shield plate and a wafer according to a second embodiment;

FIG. 7 is a cross-sectional view showing a shield plate and a wafer according to a third embodiment; and

FIG. 8 is a cross-sectional view showing a shield plate and a wafer according to a fourth embodiment.

### DETAILED DESCRIPTION

An aspect of the present embodiment, there is provided a shield plate configured to cover a semiconductor substrate including a semiconductor device in which a first semiconductor element and a second semiconductor element are included, in implanting charged particles into the semiconductor substrate to provide a lifetime control layer in the semiconductor substrate, including, an alignment mark configured to align with respect to a semiconductor substrate, a first region configured to cover the first semiconductor element, and a second region configured to cover the second semiconductor element, a thickness of the second region being thinner than a thickness of the first region.

Another aspect of the present embodiment, there is provided a method for manufacturing a semiconductor device, including providing a first semiconductor element and a second semiconductor element on a semiconductor substrate, bonding a first shield plate onto the semiconductor substrate, the first shield plate including an alignment mark in order to align with respect to the semiconductor substrate, a first region and a second region, a thickness of the second region being thinner than a thickness of the first region, and implanting charged particles into the semiconductor substrate in a state that the first semiconductor element and the second semiconductor covered with the first region and the second region, respectively.

Another aspect of the present embodiment, there is provided a semiconductor device, including an insulated gate bipolar transistor;

a reverse-conducting diode, at least one lifetime control layer formed in the reverse-conducting diode.

Hereinafter, embodiments will be described in detail with reference to the drawings.

### First Embodiment

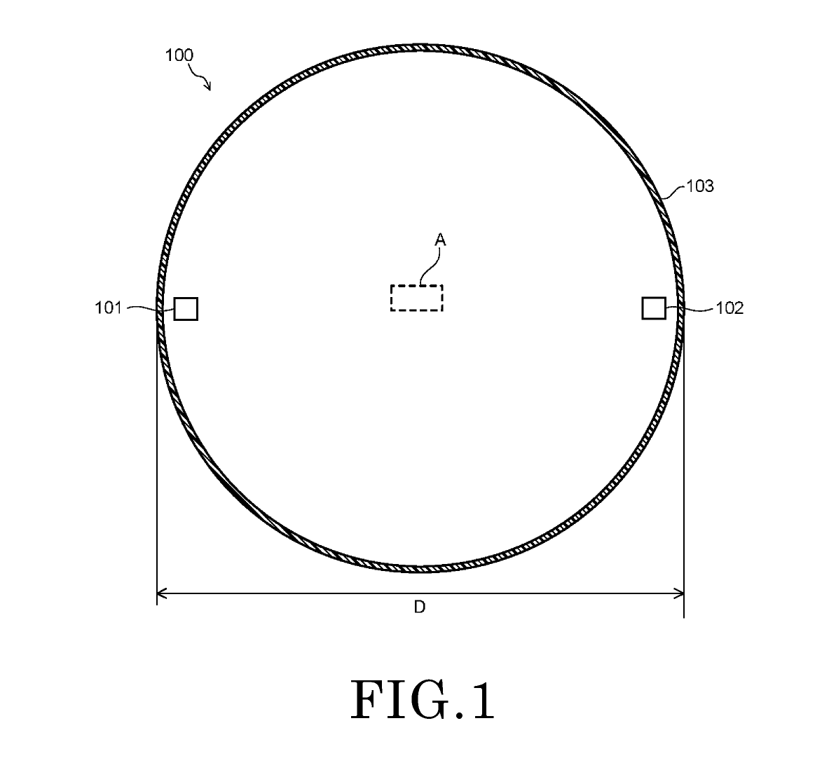

FIG. 1 is a plan view showing a shield plate 100 according to a first embodiment.

The shield plate 100 is used when a lifetime control layer is formed by implanting charged particles, for example, hydrogen ions or helium ions into a semiconductor device formed on a semiconductor substrate (wafer). Here, the semiconductor substrate refers to a reverse-conducting insulated gate bipolar transistor of a combination of an insulated gate bipolar transistor (IGBT element) and a reverse-conducting diode (diode element).

The shield plate 100 is formed of metal. Examples of the metal include aluminum, nickel, tungsten, molybdenum, titan, alloys of aluminum, nickel, tungsten, molybdenum, and titan, stainless steel, and silicon. The shield plate 100 is circular. The shield plate 100 has a diameter D almost equal to a diameter of the wafer as a shielded target. A bonding agent 103 is applied to a circumference of the shield plate 100. The bonding agent 103 serves to temporarily bond the wafer. Note that a region to which the bonding agent 103 is applied is favorably set to a range of 1 mm to 3 mm from the edge of the shield plate 100. Typically, the semiconductor device is not formed in a region having a range of several mm, typically about 2 mm, from the edge of the wafer. Therefore, by setting the region to which the bonding agent 103 is applied to the range of 1 mm to 3 mm, for example, from the edge of the shield plate 100, the semiconductor device formed on the wafer can be prevented from being bonded with the bonding agent 103.

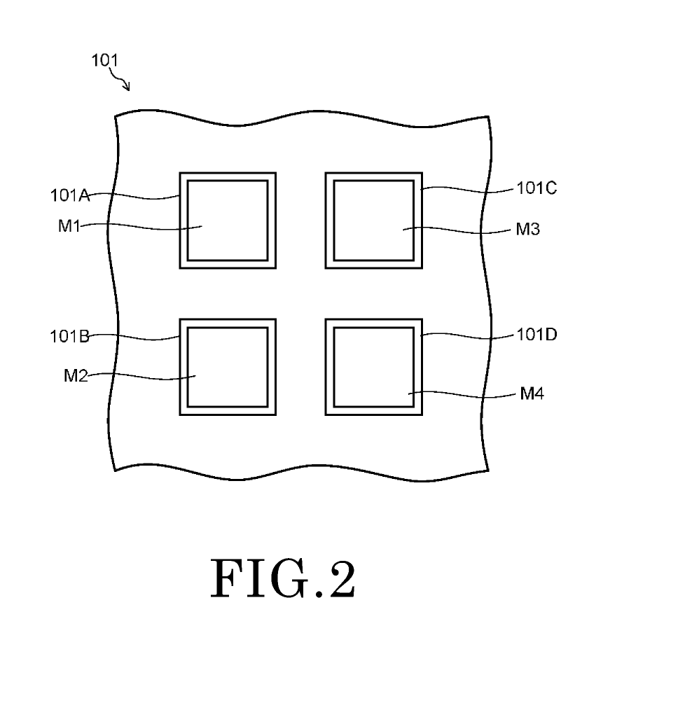

Further, alignment marks 101, 102 for alignment are formed at the edges of the shield plate 100. FIG. 2 is a plan view showing the alignment mark 101. Note that the alignment mark 102 has the same configuration as that of the alignment mark 101. As shown in FIG. 2, the alignment mark 101 includes four openings 101A to 101D formed in the shield plate 100. The openings 101A to 101D each have a rectangular shape. The openings 101A to 101D are arranged in a matrix form.

Four rectangular marks M1 to M4 are formed at positions in the wafer that correspond to the four openings 101A to 101D of the alignment mark 101. The marks M1 to M4 each have an area slightly smaller than an area of each of the openings 101A to 101D. The marks M1 to M4 are arranged in a matrix form similar to the openings 101A to 101D. Further, four rectangular marks M1 to M4 (not shown) are also formed at positions in the wafer that correspond to four openings (not shown) of the alignment mark 102.

The position of the shield plate 100 to the wafer is defined by aligning the four openings of each of the alignment marks 101, 102 with the marks M1 to M4 formed in the wafer. At that time, alignment is performed such that all the marks M1 to M4 can be seen through the openings 101A to 101D of the alignment mark 101 as viewed in a top view, respectively. Further, alignment of the alignment mark 102 is performed in the same way as the alignment of the alignment mark 101. Note that, in the first embodiment, the two alignment marks 101, 102 are formed in the shield plate 100. However, the number of alignment marks is not limited to two. Additionally, transparent materials such as glass may be fitted into the openings 101A to 101D constituting the alignment marks 101, 102.

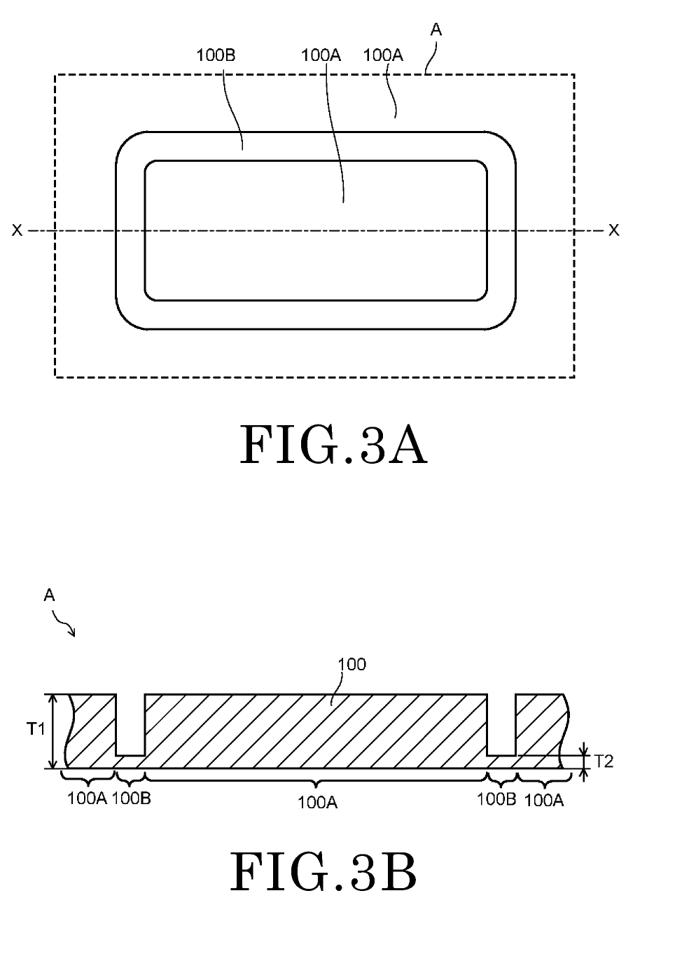

FIG. 3A is an enlarged plan view showing a region A of FIG. 1. FIG. 3B is a cross-sectional view taken along the line X-X (alternate long and short dash line) of FIG. 3A. As shown in FIGS. 3A and 3B, the shield plate 100 includes thick regions 100A and a region 100B thinner than the regions 100A. A thickness T1 of the regions 100A of the shield plate 100 is set so that no charged particles can pass through the regions 100A. Further, a thickness T2 of the region 100B of the shield plate 100 is set so that charged particles can pass through the region 100B.

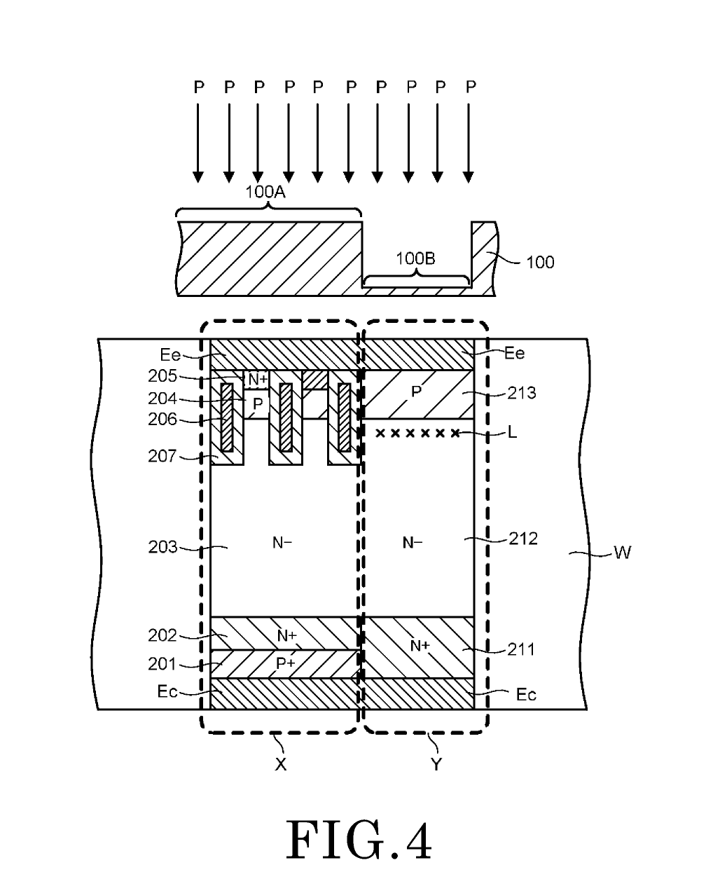

FIG. 4 is a partially cross-sectional view showing the shield plate 100 and a wafer W being the shielded target. A plurality of reverse-conducting insulated gate bipolar transistors is formed on the wafer W. The wafer W includes regions X in which insulated gate bipolar transistors (IGBT elements) are formed (hereinafter, referred to as IGBT element-forming regions X) and regions Y in which reverse-conducting diodes (diode elements) are formed (hereinafter, referred to as diode element-forming regions Y).

More particularly, the IGBT element formed in each of the IGBT element-forming regions X includes a P⁺-collector layer 201, an N⁺ buffer layer 202, an N⁻-drift layer 203, a P-base layer 204, an N⁺ emitter layer 205, gate electrodes 206, gate insulating films 207, a collector electrode Ec, and an emitter electrode Ee. The P⁺-collector layer 201, the N⁺-buffer layer 202, the N⁻-drift layer 203, the P-base layer 204, and the N⁺-emitter layer 205 are stacked in the stated order. The gate electrodes 206 and the gate insulating films 207 extend through the N⁺-emitter layer 205 and the P-base layer 204 to the N⁻-drift layer 203.

The diode element formed in each of the diode element-forming regions Y includes an N⁺ collector layer 211, an N⁻-base layer 212, a P emitter layer 213, a collector electrode Ec (cathode side), and an emitter electrode Ee (anode side).

The alignment marks 101, 102 of the shield plate 100 are aligned with the marks M1 to M4 (not shown) formed in the wafer W. Then, as shown in FIG. 4, the shield plate 100 is positioned with respect to the wafer W such that the thick regions 100A of the shield plate 100 cover the IGBT element-forming regions X and the thin region 100B of the shield plate 100 covers the diode element-forming regions Y.

In such a state, the charged particles are radiated to the wafer W through the shield plate 100. Charged particles P are not radiated to the IGBT element-forming regions X covered with the thick regions 100A. On the other hand, the charged particles P are radiated to the diode element-forming regions Y covered with the thin region 100B. That is, by covering the wafer W with the shield plate 100, the charged particles can be radiated only to the diode element-forming regions Y to form a lifetime control layer L only in the diode element-forming regions Y.

(Method for Manufacturing Semiconductor Device)

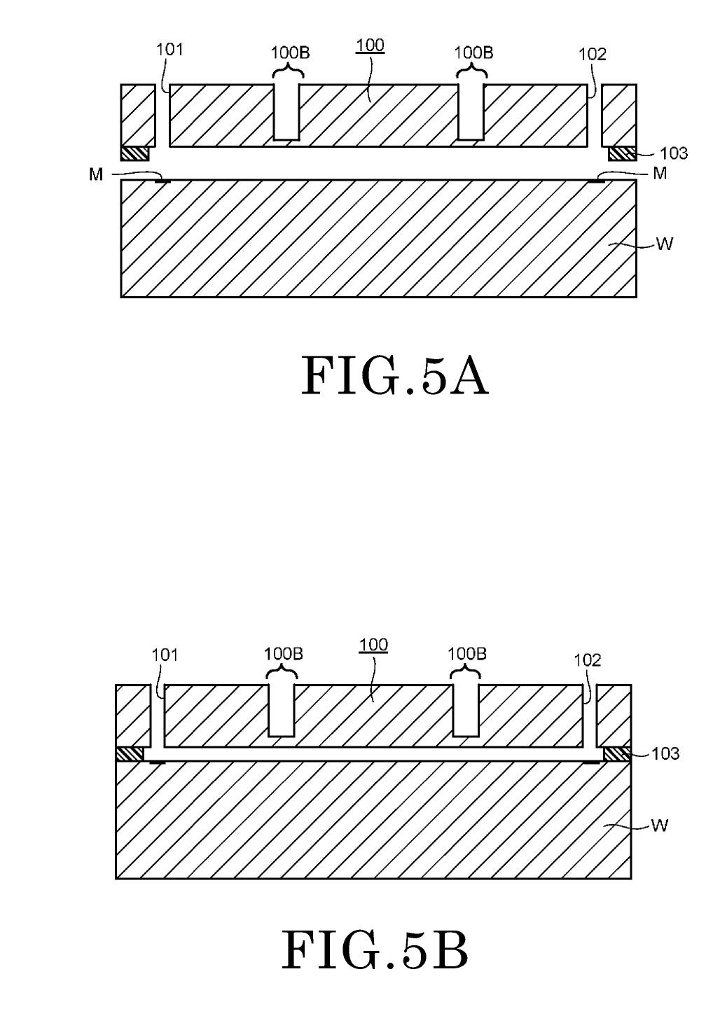

Subsequently, a method for manufacturing a reverse-conducting insulated gate bipolar transistor using the shield plate 100 described above with reference to FIGS. 1 to 4 will be described. FIGS. 5A to 5D are cross-sectional views showing a process for manufacturing a reverse-conducting insulated gate bipolar transistor. Hereinafter, referring to FIGS. 5A to 5D, the process for manufacturing a reverse-conducting insulated gate bipolar transistor will be described.

First, the wafer W on which the reverse-conducting insulated gate bipolar transistor including the IGBT element and the diode element is formed is prepared. Subsequently, utilizing the alignment marks 101, 102 of the shield plate 100 and marks M formed in the wafer W, the shield plate 100 is positioned with respect to the wafer W (see FIG. 5A).

Subsequently, the shield plate 100 is bonded to the wafer W such that a space is provided between the wafer W and the shield plate 100 (see FIG. 5B).

Subsequently, the charged particles P are radiated to the wafer W through the shield plate 100 (see FIG. 5C). The charged particles P pass through the thin region 100B and do not pass through the thick regions 100A. Therefore, the charged particles P are radiated only to the regions of the wafer W in which the diode elements are formed. The lifetime control layer L with a desired depth is formed in each diode element irradiated with the charged particles P (see FIG. 5D).

Positions at which the charged particles P stop can be controlled by adjusting an accelerating voltage of the charged particles P. That is, the lifetime control layer L can be formed at a desired depth by adjusting the accelerating voltage of the charged particles P. Note that, after the lifetime control layer L is formed, annealing is favorably performed at 400° C. for 120 minutes, for example.

As described above, the shield plate 100 according to the first embodiment includes the alignment marks 101, 102. By aligning the alignment marks 101, 102 with the corresponding marks M of the wafer, the thick regions 100A are aligned with the IGBT element-forming regions X of the wafer and the thin region 100B is aligned with the diode element-forming regions Y of the wafer. Therefore, the charged particles can be radiated only to the diode element-forming regions Y of the wafer. Thus, the lifetime control layer L can be formed in each diode element-forming region Y of the wafer.

Further, the bonding agent 103 for temporary bonding is applied to the area having the range of 1 mm to 3 mm from the edge of the shield plate 100. Therefore, the semiconductor device formed on the wafer can be prevented from being bonded with the bonding agent 103.

### Second Embodiment

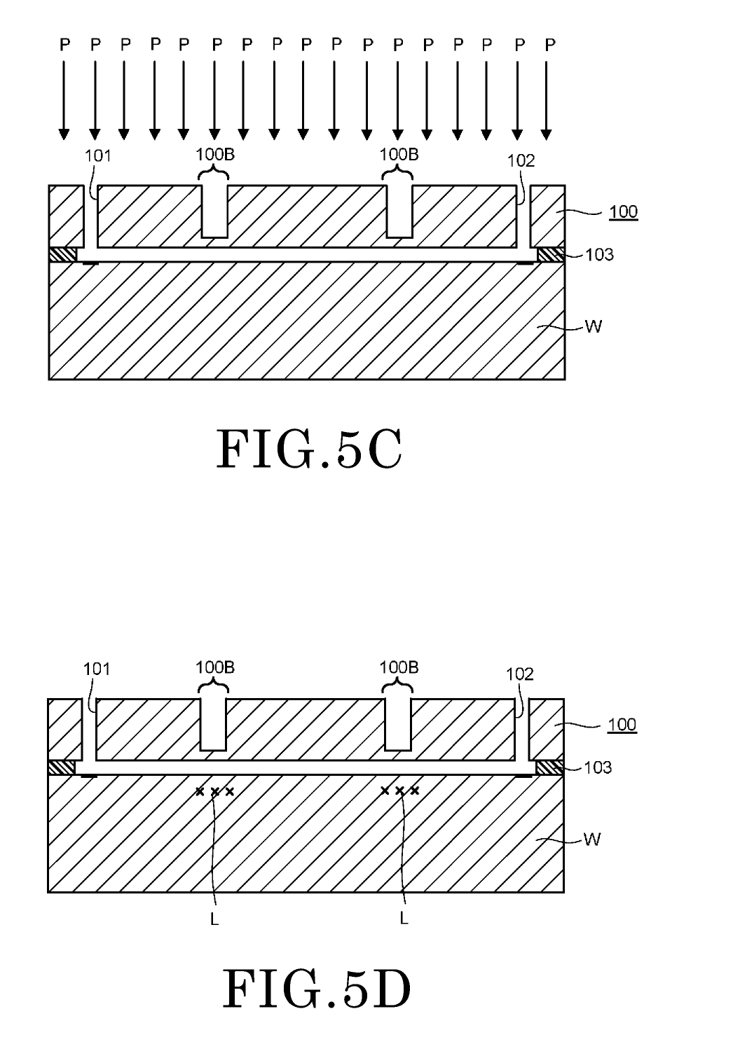

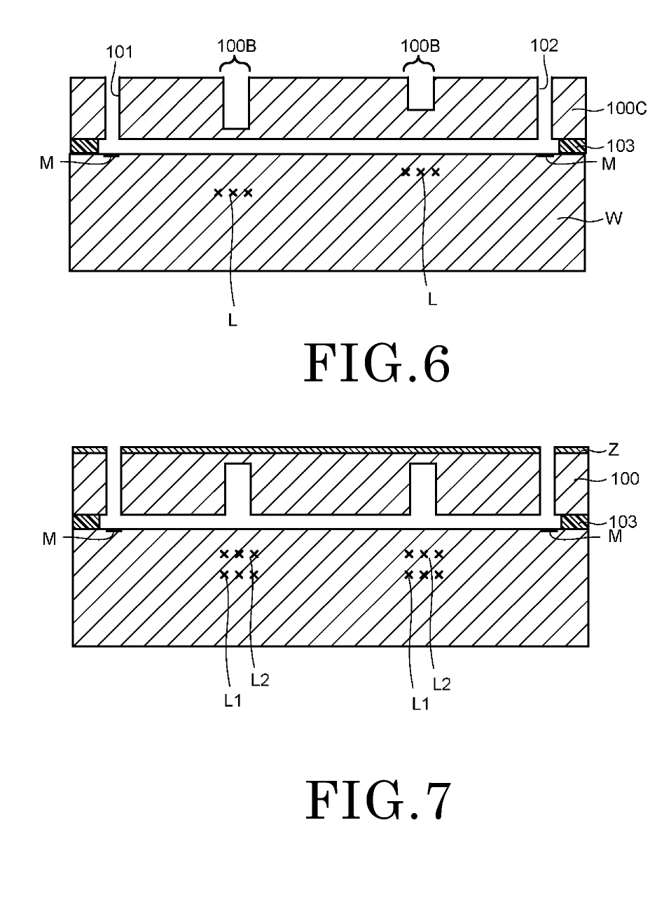

FIG. 6 is a cross-sectional view showing a shield plate 100C and a wafer W according to a second embodiment. In the first embodiment, the thin region 100B of the shield plate 100 has the same thickness. However, as in the shield plate 100C shown in FIG. 7, a thin region 100B covering diode element-forming regions Y can have different thickness. With such a configuration, a lifetime control layer L can be formed at different depths by varying radiation depth (penetration length) of charged particles.

### Third Embodiment

FIG. 7 is a cross-sectional view showing a shield plate 100 and a wafer W according to a third embodiment. In the third embodiment, charged particles are radiated to the wafer W through the shield plate 100 to form a lifetime control layer L1, and then the shield plate 100 is covered with a flat plate Z. A lifetime control layer L2 is formed by radiating the charged particles to the wafer W through the shield plate 100 and the flat plate Z. With such a configuration, the lifetime control layers L1, L2 can be formed at different depths at the same position in a flat surface.

### Fourth Embodiment

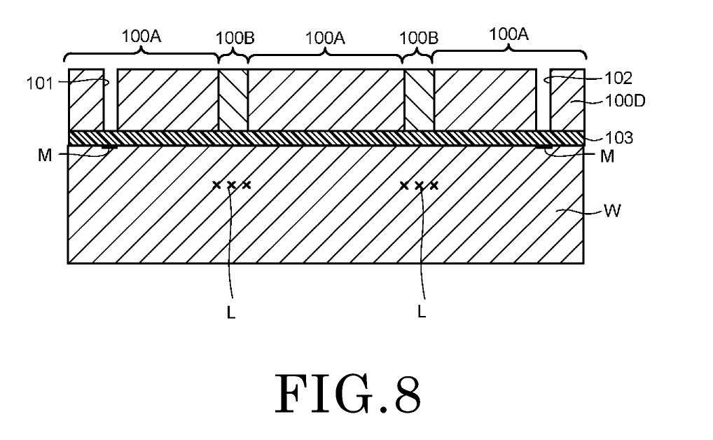

FIG. 8 is a cross-sectional view showing a shield plate 100D and a wafer W according to a fourth embodiment. In the fourth embodiment, regions 100A and a region 100B of the shield plate 100D are formed of different materials. Specifically, a heavy-element material having a high shielding capability for charged particles, for example, tungsten is used for the regions 100A covering IGBT element-forming regions X. A light-element material having a low shielding capability for charged particles, for example, aluminum is used for the region 100B covering diode element-forming regions Y. With such a configuration, a surface of the shield plate 100D is formed to be a flat surface without irregularities. Therefore, the shield plate 100D can be used as a reinforce plate when the thickness of the wafer W is reduced by grinding a back surface of the wafer W.

Note that, in the case where the shield plate 100D is used as the reinforce plate for grinding, a bonding agent for temporary bonding is applied over the entire shield plate 100D before bonding is performed. Further, regarding implantation of charged particles, charged particles may be implanted after the bonding agent in an outer periphery is left and the remaining bonding agent is removed. Alternatively, charged particles may be implanted while the bonding agent is left without removing the bonding agent.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A shield plate configured to cover a semiconductor substrate comprising a semiconductor device in which a first semiconductor element and a second semiconductor element are comprised, in implanting charged particles into the semiconductor substrate to provide a lifetime control layer in the semiconductor substrate, comprising:
an alignment mark configured to align with respect to a semiconductor substrate;
a first region configured to cover the first semiconductor element; and
a second region configured to cover the second semiconductor element, a thickness of the second region being thinner than a thickness of the first region.

2. The shield plate of claim 1, wherein
the alignment mark includes a plurality of openings arranged as a matrix form, and each of the openings has a rectangular shape.

3. The shield plate of claim 1, wherein
the first semiconductor element is an insulated gate bipolar transistor and the second semiconductor is a reverse-conducting diode.

4. The shield plate of claim 1, wherein
the shield plate is composed of a metal or silicon.

5. The shield plate of claim 1, wherein
the second region has a plurality of thicknesses.

6. The shield plate of claim 1,
wherein a material of the first region is different from a material of the second region.

7. A method for manufacturing a semiconductor device, comprising:
providing a first semiconductor element and a second semiconductor element on a semiconductor substrate;
bonding a first shield plate onto the semiconductor substrate, the first shield plate including an alignment mark in order to align with respect to the semiconductor substrate, a first region and a second region, a thickness of the second region being thinner than a thickness of the first region; and
implanting charged particles into the semiconductor substrate in a state that the first semiconductor element and the second semiconductor covered with the first region and the second region, respectively.

8. The method for claim 7, wherein
the alignment mark includes a plurality of openings arranged as a matrix form, and each of the openings has a rectangular shape.

9. The method for claim 7, wherein
the bonding of the first shield plate onto the semiconductor substrate is performed in a state that a space is provided between the first shield plate and the semiconductor substrate.

10. The method for claim 7, further comprising;
applying a bonding agent on a periphery region of the first shield plate to temporarily bond between the first shield plate and the semiconductor substrate before the bonding of the first shield plate to the semiconductor substrate.

11. The method for claim 7, further comprising;
grinding a back surface of the semiconductor substrate after the implanting of the charged particles.

12. The method for claim 11, further comprising;
applying a bonding agent over an entire first shield plate to temporarily bond between the first shield plate and the semiconductor substrate before the bonding of the first shield plate to the semiconductor substrate.

13. The method for claim 7, further comprising;
bonding a second shield plate onto the first shield plate, and implanting charged particles into the semiconductor substrate via the first shield plate and the second shield plate.

14. The method for claim 7, wherein
the first semiconductor element is an insulated gate bipolar transistor and the second semiconductor is a reverse-conducting diode.

15. The method for claim 7, wherein
the second region has a plurality of thicknesses.

16. The method for claim 7, wherein
wherein a material of the first region is different from a material of the second region.

17. A semiconductor device, comprising:
an insulated gate bipolar transistor;
a reverse-conducting diode;
at least one lifetime control layer formed in the reverse-conducting diode.

18. The semiconductor device of claim 17, wherein
the plurality of the lifetime control layers are included in the reverse-conducting diode, each lifetime control layer is arranged in a different region in depth.

19. The semiconductor device of claim 17, wherein
the plurality of the lifetime control layers are included in the reverse-conducting diode, each lifetime control layer is arranged in a different region of a same plane in depth.
